(19) United States
(12) Patent Application Publication
(10) Pub. No.: US 2011/0088757 A1
(43) Pub. Date: Apr. 21, 2011

(54) Photovoltaic Cell

(76) Inventors: Donald James Highgate, Surrey (GB); Lindsey Harrison, Sheffield (GB); Simon Bourne, Sheffield (GB)

(21) Appl. No.: 10/568,241

(22) PCT Filed: Aug. 19, 2004
(86) PCT No.: PCT/GB2004/003570

§ 371 Date: Mar. 8, 2007

(30) Foreign Application Priority Data
Aug. 22, 2003 (GB) 0319799.3

(51) Int. Cl. H01L 31/04

(52) U.S. Cl. 136/252

(57) ABSTRACT

The present invention involves the use of a membrane electrode assembly, i.e. a cathode/membrane/anode assembly capable of transmitting light. A first aspect of the invention is a photovoltaic cell which is a membrane electrode assembly capable of transmitting light. The membrane material is preferably a polymer comprising a strongly ionic group. The assembly preferably comprises a catalyst and/or a dye sensitiser. A second aspect of the invention is a method for generating a voltage which comprises irradiating a cell of the invention.

### FIELD OF THE INVENTION

This invention relates to a photovoltaic cell.

### BACKGROUND OF THE INVENTION

A photovoltaic cell converts light energy into electrical energy, the “photovoltaic effect” being the process through which light energy is converted into electrical energy. Photovoltaic cells are typically solid state devices, usually semiconductors such as silicon. Usually one or more photosensitive electrodes are irradiated, simultaneously generating a voltage and a current.

Electrochemical cells may be in the form of a membrane electrode assembly (MEA), i.e. a cathode/membrane/anode assembly. MEAs typically have a multi-layered structure comprising (i) an Ion Exchange Membrane (IEM), (ii) a current-collecting electrode, and (iii) an electro-catalyst layer on each side.

WO-A-03/023890 describes a composite MEA formed by an in situ polymerisation process. This publication further describes an MEA having an improved reaction interface.

### SUMMARY OF THE INVENTION

The present invention addresses the need for an efficient method of generating electrical energy via the photovoltaic effect. The invention involves the use of a MEA capable of transmitting light.

A first aspect of the invention is a photovoltaic cell which is a membrane electrode assembly capable of transmitting light. The membrane material is preferably a polymer comprising a strongly ionic group. The assembly preferably comprises a catalyst and/or a dye sensitiser.

A second aspect of the invention is a method for generating a voltage, which comprises irradiating a cell of the invention.

### DESCRIPTION OF THE PREFERRED EMBODIMENTS

The term “photovoltaic cell” as used herein refers to a cell which is capable of converting light energy into electrical energy.

The term “membrane electrode assembly” as used herein refers to a cathode/membrane/anode assembly.

The membrane may be capable of transmitting light. For example, the membrane may comprise one or channels for the transmission of light or may be optically transparent, preferably optically clear. The membrane material may be transparent to photons, e.g. high energy, visible or UV radiation. It is preferably malleable, so that it can formed into shapes which focus, concentrate and direct light as desired. Thus, for example, the MEA may be in the form of a light waveguide or lens.

The membrane material preferably comprises a polymer which includes a strongly ionic group. The membrane may be formed by the polymerisation of monomers which include monomers such as hydroxyethyl methacrylate (HEMA), acrylonitrile (AN), methyl methacrylate (MMA), 2-acrylamido-2-methyl-1-propanesulphonic acid (AMPSA) and/or vinyl pyrrolidone (VP).

The material may be formed by the copolymerisation of monomers which include an electrically active comonomer. The electrically active component can be based either upon an acid, e.g. a sulphonic acid (SO₃), phosphoric or phosphonic acid, or an alkali (OH), e.g. KOH or NaOH or ammonium hydroxide. If electrically inactive comonomers are used, the material may be rendered electrically active by introducing strongly ionic molecules, for example using a swelling liquid technique.

Water can be used to cool the cell, maintain hydration and carry away excess energy as heat energy. Accordingly, the polymer is preferabl_{y} hydrophilic, such that it is inherently able to absorb and transmit water throughout its molecular structure. Hydrophilic polymers can typically be formed by the copolymerisation from solution of a monomer mixture normally consisting of a hydrophobic/structural comonomer and a hydrophilic comonomer. The polymer is preferably cross-linked for greater stability. Cross-linked materials may be formed by applying ionising radiation to the material or by using a cross-linking agent. The use of additional cross-linking agents allows the final water uptake to be controlled separately from the electrical properties. The membrane may comprise integrated channels for the transmission of water.

The assembly may comprise a suitable catalyst. Preferred catalysts include platinum and titanium dioxide. A dye sensitiser such as ruthenium (II) tris(2,2′-bipyridine)dichloride hexahydrate (ie. a compound of Ru(bpy)₃²⁺), iodine or an iron complex with a suitable quenching compound (e.g. methyl violagen) may be used. Preferably, the sensitiser is disposed throughout the membrane. Any catalyst is preferably disposed on or near an electrode.

An electrode may be translucent, transparent (e.g. a tin oxide glass) or of an “open-weave” construction, to allow the transmission of photons through the electrode to reach the membrane. A carbon fabric may be used as an electrode, and the fabric may be impregnated with a layer of catalyst. The assembly may be in the form of a stack of individual MEAs.

Further information regarding suitable materials and processes for the formation of MEAs may be found in WO-A-03/023890.

The following Examples illustrate the invention.

### EXAMPLE 1

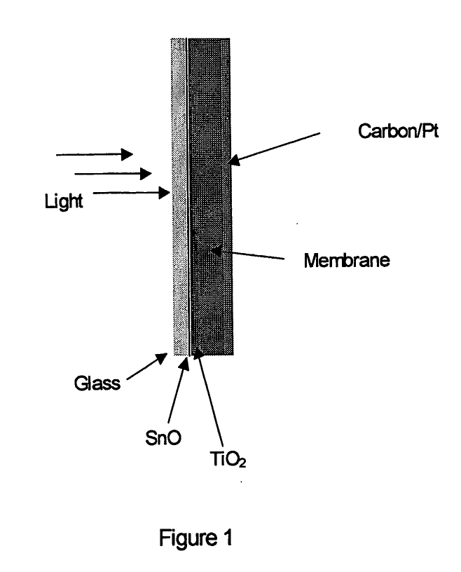

A cell of the invention was constructed using an AN-VP-AMPSA copolymer membrane. The electrode-catalyst systems used were tin oxide glass coated with titanium dioxide and carbon fabric coated with platinum. The cell is depicted in FIG. 1.

A “blue” lamp (100 W electrical output) was used to illuminate the cell. The output of the cell was measured and was found to depend entirely on the presence of light, giving an open circuit voltage of 0.59 V. The resulting current was dependent upon the light flux, reaching a maximum of 0.22 mA/cm².

### EXAMPLE 2

A cell similar to that of Example 1 was produced, except that t/he membrane was formed by thermal polymerisation of the monomers in situ with the glass electrode plate.

The cell was irradiated as before, giving an open circuit voltage of 0.78 V.

1. A photovoltaic cell which is a membrane electrode assembly capable of transmitting light.

2. The cell according to claim 1, wherein the membrane is a material comprising a polymer, the polymer comprising a strongly ionic group.

3. The cell according to claim 2, wherein the polymer is hydrophilic.

4. The cell according to claim 2, wherein the polymer is cross-linked.

5. The cell according to claim 1, wherein the membrane is a malleable material.

6. The cell according to claim 1, wherein the assembly is in the form of a stack.

7. The cell according to claim 1, wherein the assembly comprises a catalyst.

8. The cell according to claim 7, wherein the catalyst comprises platinum and/or titanium dioxide.

9. The cell according to claim 1, wherein the membrane comprises a channel suitable for the transmission of light.

10. The cell according to claim 1, wherein the membrane is optically transparent.

11. The cell according to claim 1, wherein the assembly comprises a dye sensitizer.

12. The cell according to claim 1, wherein the assembly is planar in structure.

13. The cell according to claim 1, wherein an electrode is transparent.

14. A method for generating a voltage, wherein said method comprises irradiating a photovoltaic cell that is a membrane electrode assembly capable of transmitting light.

15. The method, according to claim 14, wherein the membrane is a material comprising a polymer.

16. The method, according to claim 15, wherein the polymer is hydrophilic and/or cross-linked.

17. The method, according to claim 14, wherein the assembly comprises a catalyst.

18. The method, according to claim 14, wherein the membrane comprises a channel suitable for the transmission of light.

19. The method, according to claim 14, wherein the membrane is optically transparent.

20. The method, according to claim 14, wherein the assembly comprises a dye sensitizer.
